(19) United States
(12) Patent Application Publication
(10) Pub. No.: US 2014/0104721 A1
(43) Pub. Date: Apr. 17, 2014

(54) DUMMY HARD DISK DRIVE

(71) Applicants: Hon Hai Precision Industry Co., Ltd., New Taipei (TW); Hong Fu Jin Precision Industry (ShenZhen) Co., Ltd., Shenzhen (CN)

(72) Inventor: LEI LIU, Shenzhen (CN)

(21) Appl. No.: 13/927,146

(22) Filed: Jun. 26, 2013

(30) Foreign Application Priority Data
Oct. 16, 2012 (CN) 2012103905586

(51) Int. Cl. G01R 35/00

(52) U.S. Cl. CPC G01R 35/007
USPC 360/69

(57) ABSTRACT

A dummy hard disk drive (HDD) includes an HDD interface, a control module, and a heat-generation unit. The HDD interface is used to receive a voltage. The control module is connected to the HDD interface and includes a number of branch circuits connected in parallel. Each branch circuit includes a current limiting resistor and a switch connected in series. The heat-generation unit is connected between the control module and ground to generate heat based on current flowing through the heat-generation unit.

### BACKGROUND

1. Technical Field

The present disclosure relates to a dummy hard disk drive.

2. Description of Related Art

Many power consumption tests are performed on a motherboard or other components. However, it is costly to purchase different types of hard disk drives for the test when the hard disk drives are just used to test power consumption.

Therefore, there is room for improvement in the art.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is a block diagram of an embodiment of a dummy hard disk drive of the present disclosure.

FIG. 2 is a circuit diagram of the dummy hard disk drive of FIG. 1.

### DETAILED DESCRIPTION

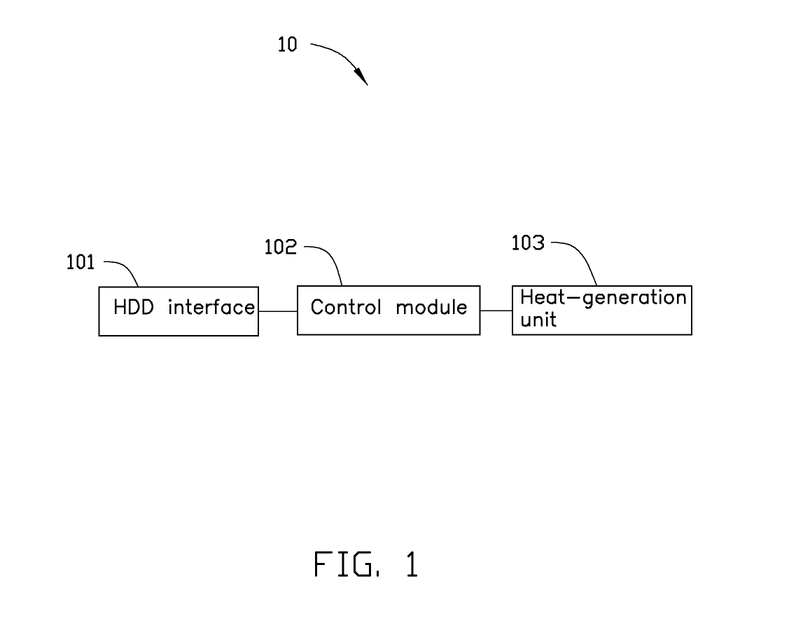

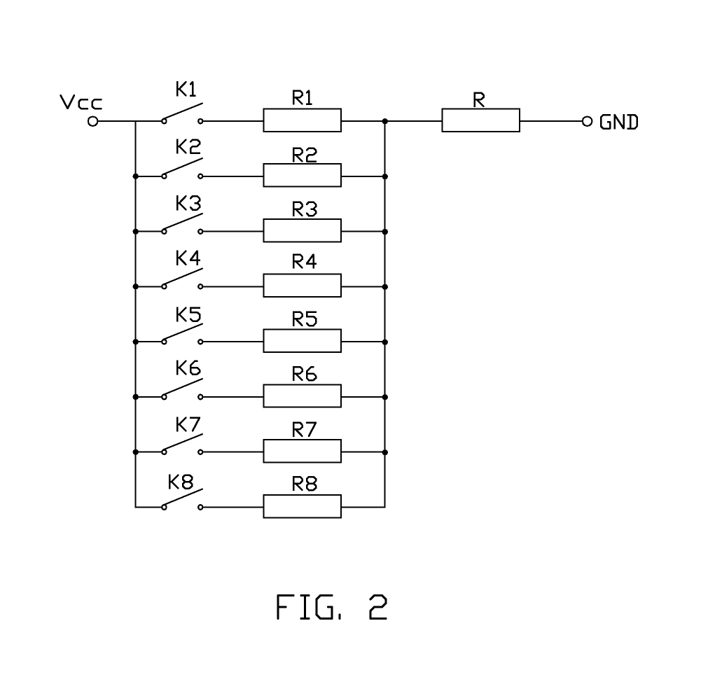

FIG. 1 and FIG. 2 show an embodiment of a dummy hard disk drive (HDD) 10 of the present disclosure. The dummy HDD 10 includes an HDD interface 101, a control module 102, and a heat-generation unit 103. The HDD interface 101 is used to connect to an HDD connector of a motherboard to receive a voltage Vcc. In the embodiment, the HDD interface is a 29 pin serial attached small computer system interface (SAS) connector. The SAS connector is a standard HDD connector. The dummy HDD 10 could be used to simulate different kinds of current HDDs.

The control module 102 is connected to the HDD interface 101 to receive the voltage Vcc. The control module 102 includes a plurality of current limiting resistors and a plurality of switches. In the embodiment, the current limiting resistors include resistors R1 to R8, and the switches include switches K1 to K8. First ends of the switches K1 to K8 are all connected to the HDD interface 101 to receive the voltage Vcc. Second ends of the switches K1 to K8 are connected to a first end of the heat-generation unit 103 through the current limiting resistors R1 to R8, respectively. A second end of the heat-generation unit 103 is grounded. In the embodiment, the heat-generation unit 103 is a heat producing resistor R. The resistor R generates heat based on the current flowing through the resistor R. The voltage could be, for example, 5 volts (V) or 12V.

A value of the current in the control module 102 differs when using different numbers of current limiting resistors. The operation voltage and operation current of current HDDs are known, and the control module 102 can simulate the current HDDs by selecting the corresponding resistance using the switches K1 to K8.

In the embodiment, The dummy HDD 10 with resistors R1 to R8 can be used to simulate eight kinds of current HDDs by closing a corresponding one of the switches K1-K8, to test power consumption of the current HDDs. In other embodiments, the control module 102 may include one or more indicators to indicate, for example, power consumption related to the simulated HDD current chosen.

The dummy HDD 10 is connected to the HDD connector through the HDD interface 101. There is an ordinary HDD on the motherboard to make the motherboard boot normally. When using The dummy HDD 10, one of the switches K1-K8 is selectively closed to select the current through the resistor R, according to which HDD is to be simulated.

While the disclosure has been described by way of example and in terms of preferred embodiment, it is to be understood that the disclosure is not limited thereto. To the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A dummy hard disk drive (HDD), comprising:
an HDD interface to receive a voltage;
a control module connected to the HDD interface, wherein the control module comprises a plurality of branch circuits connected in parallel, each branch circuit comprises a current limiting resistor and a switch connected in series; and
a heat-generation unit connected between the control module and ground, to generate heat based on current flowing through the heat-generation unit.

2. The dummy HDD of claim 1, wherein the HDD interface is a 29 pin serial attached small computer system interface (SAS) connector.

3. The dummy HDD of claim 1, wherein the heat-generation unit is a heat producing resistor.
